(19) United States
(12) Patent Application Publication
(10) Pub. No.: US 2008/0093635 A1
(43) Pub. Date: Apr. 24, 2008

(54) Junction Fet and Method of Manufacturing the Same

(75) Inventor: Shunsuke KOBAYASHI, Gunma (JP)

Correspondence Address: MORRISON & FOERSTER LLP, 1650 TYSONS BOULEVARD, SUITE 400, MCLEAN, VA, 22102, US

(73) Assignees: Sanyo Electric Co., Ltd., Moriguchi-shi (JP); Sanyo Semiconductor Co., Ltd., Ora-gun (JP)

(21) Appl. No.: 11/877,412

(22) Filed: Oct. 23, 2007

(30) Foreign Application Priority Data
Oct. 23, 2006 (JP) 2006-287906

(51) Int. Cl. H01L 29/808; H01L 21/337

(52) U.S. Cl. 257/256; 438/186; 257/E29.312; 257/E21.446

(57) ABSTRACT

A shallow channel region is selectively formed by ion implantation and diffusion. Since the channel region forms pn junctions with a p type semiconductor layer having a relatively low impurity concentration, a reduction of a junction capacitance leads to improvement in high-frequency characteristics. Moreover, since a gate region can also be shallowly formed by ion implantation, noise can be reduced by reduction in an internal resistance. Furthermore, a breakdown voltage and electrostatic breakdown characteristics can be improved by allowing the source and drain regions to penetrate the channel region.

This application claims priority from Japanese Patent Application Number 2006-287906 filed Oct. 23, 2006, the content of which is incorporated herein by reference in its entirety.

### BACKGROUND OF THE INVENTION

1. Field of the Invention

The present invention relates to a junction FET and a manufacturing method of the junction FET, and more particularly relates to a high breakdown-voltage junction FET capable of improving high-frequency characteristics and noise characteristics and a method of manufacturing the junction FET.

2. Description of the Related Art

In a conventional junction FET, for example, an n type well region to be a channel region is provided in a p type semiconductor substrate, n+ type source and drain regions are provided in the n type well region, and a gate region is formed between the source and drain regions. This technology is described for instance in Japanese Patent Application Publication No. Hei 8-227900.

With reference to FIGS. 9A and 9B, a conventional junction FET 200 will be described. FIG. 9A is a plan view showing the conventional junction FET 200 and FIG. 9B is a cross-sectional view along the line b-b in FIG. 9A.

After a p type epitaxial layer 22 is grown on a p type substrate 21, an n type epitaxial layer is formed. Thereafter, a p+ type isolation region 23 that reaches the p type substrate 21 is formed to define and surround an n type well region 24. The n type well region serves as a channel region 24.

An n+ type source region 25 and an n+ type drain region 26 are formed from a surface of the channel region 24, and a source electrode 29 and a drain electrode 30 are connected to the source region 25 and the drain region 26, respectively, through contact holes provided in an insulating film 40. Moreover, a gate region 27 is formed between the source region 25 and the drain region 26.

With reference to FIGS. 10A to 10D, a method for manufacturing the conventional junction FET 200 will be described.

First, a p type epitaxial layer 22 and an n type epitaxial layer 24′ are laminated on a p type substrate 21, and an n type well region 24 to be a channel region is isolated by a p+ type isolation region (ISO) 23 (FIG. 10A). Next, an opening is provided at a predetermined position in an oxide film 40, and p type impurities are implanted into the opening and diffused therein to form a p+ type gate region 27. In this event, an impurity concentration is an order of 10¹⁸ cm⁻³ (FIG. 10B). Thereafter, openings are provided at predetermined positions in the oxide film 40 for forming source and drain regions 25 and 26, and n type impurities (for example, phosphorus (P)) are implanted into the openings and diffused therein to form n+ type source and drain regions 25 and 26 (FIG. 10C). Furthermore, a source electrode 29 and a drain electrode 30 which come into contact with the source region 25 and the drain region 26, respectively, are formed, and a gate electrode 31 is formed on a back surface (FIG. 10D).

High-frequency characteristics are important to a junction FET used in an RF (high-frequency) amplifier. In the conventional junction FET 200, the channel region 24 cannot be formed to have a small depth d21 (see FIG. 9B). Thus, when the junction FET is used in the RF amplifier, the junction FET is generally used in a relatively low frequency band of about 1 MHz, for example.

Here, a cutoff frequency f_{T} representing high-frequency characteristics of the junction FET significantly depends on a pn junction capacitance formed by the channel region 24, the p type epitaxial layer 22 and the p+ type isolation region 23. Specifically, reduction in the pn junction capacitance contributes to improvement of the cutoff frequency f_{T}.

Meanwhile, as shown in FIGS. 10A to 10D, the conventional channel region 24 is formed by using the isolation region to isolate the n type epitaxial layer 24′. The n type epitaxial layer 24′ has a thickness limit of about 2 μm, for example. When the thickness thereof is smaller than the limit, it is difficult to control a variation in formation of the epitaxial layer. More specifically, there is a problem of varying characteristics of the channel region 24.

In other words, in the conventional structure, a pn junction area formed by the channel region 24, the p type epitaxial layer 22 and the p+ type isolation region 23 is constrained by the thickness of the n type epitaxial layer 24′ (the depth of the channel region 24) d21. Thus, there is a problem that improvement of high-frequency characteristics cannot be achieved by reduction in the pn junction capacitance.

Moreover, the conventional structure has a problem of making little progress on improving noise characteristics. The improvement of the noise characteristics requires reduction in a leak current or reduction in an internal resistance of an operation part. However, in the junction FET 200 having the conventional structure, a leak current inevitably occurs in the pn junction formed by the channel region 24 and the p type regions therearound, which are to serve as the operation part.

Specifically, in the structure shown in FIGS. 9A and 9B, the channel region 24 is formed by isolating the n type epitaxial layer 24′ with the p type isolation region (ISO) 23. Moreover, the gate region 27 comes into contact with the isolation region (ISO) 23 provided around the channel region 24 and is connected to the gate electrode 31 on the back surface of the substrate through the isolation region 23. More specifically, in order to lower an input resistance of the device, the p type isolation region 23 serving as a current path has a high impurity concentration (1E19 cm⁻³ or more). Thus, there is a large difference in the impurity concentration at the pn junction between the channel region 24 and the isolation region 23. Consequently, the leak current is also increased.

Moreover, when the channel region 24 has the large depth d21 as described above, reduction in the internal resistance of the operation part is also hindered. I_{DSS} (or a pinch-off voltage) of the junction FET 200 is determined by a depth d22 immediately below the gate region 27 (the depth from the gate region 27 to a bottom of the channel region 24), the impurity concentration of the channel region 24 and a width (gate length) w21 of the gate region 27.

Specifically, in the case where a predetermined I_{DSS} is secured by setting constant the gate length w21 and the impurity concentration of the channel region 24, the depth d22 immediately below the gate region 27 is automatically determined. Moreover, the depth d22 does not depend on the depth d21 of the channel region 24. Thus, in the case where the depth d21 of the channel region 24 cannot be set smaller than a certain depth (2 μm) as in the case of the conventional structure, it is necessary to form the gate region 27 to have a large depth d23 in order to secure the predetermined depth d22 immediately below the gate region 27.

The larger the depth d23 of the gate region 27, the longer the length of a signal path formed from the source region 25 through immediately below the gate region 27 to the drain region 26. Moreover, the gate region 27 is formed by impurity diffusion. Accordingly, when the gate region 27 is formed to have a larger depth, lateral diffusion (diffusion in horizontal directions of the substrate) is also extended. As a result, the length of the signal path cannot be reduced. Thus, the internal resistance is increased to deteriorate the noise characteristics.

Furthermore, the improvement of the noise characteristics can also be achieved by increasing the impurity concentration of the channel region 24 (to about 4E16 cm⁻³) and improving a mutual conductance gm.

However, an increase in the impurity concentration of the channel region 24 in the conventional structure leads to a problem of deterioration of a breakdown voltage.

### SUMMARY OF THE INVENTION

The invention provides a junction field effect transistor that includes a semiconductor substrate of a first general conductivity type, a semiconductor layer of the first general conductivity type disposed on the substrate, a channel region of a second general conductivity type formed in a surface portion of the semiconductor layer so as to form a pn junction with the semiconductor layer on a side and a bottom of the channel region, a source region of the second general conductivity type formed in the channel region so as to penetrate the channel region to reach the semiconductor layer, a drain region of the second general conductivity type formed in the channel region so as to penetrate the channel region to reach the semiconductor layer, and a gate region of the first general conductivity type formed in the channel region.

The invention further provides a junction field effect transistor that includes a semiconductor substrate of a first general conductivity type, a semiconductor layer of the first general conductivity type disposed on the substrate, a channel region of a second general conductivity type formed in a surface portion of the semiconductor layer so as to define an island of the channel region in the semiconductor layer, a source region of the second general conductivity type formed in the channel region so as to penetrate the channel region to reach the semiconductor layer, a drain region of the second general conductivity type formed in the channel region so as to penetrate the channel region to reach the semiconductor layer, a gate region of the first general conductivity type formed in the channel region, and a conductive layer disposed on and in contact with the gate region.

The invention further provides a method of manufacturing a junction field effect transistor that includes providing a semiconductor substrate of a first general conductivity type, forming a semiconductor layer of the first general conductivity type on the substrate, ion-implanting impurities into the semiconductor layer so as to form a channel region of a second general conductivity type, forming a source region of the second general conductivity type in the channel region so as to penetrate the channel region to reach the semiconductor layer, forming a drain region of the second general conductivity type in the channel region so as to penetrate the channel region to reach the semiconductor layer, and forming a gate region of the first general conductivity type in the channel region.

The invention further provides a method of manufacturing a junction field effect transistor that includes providing a semiconductor substrate of a first general conductivity type, forming a semiconductor layer of the first general conductivity type on the substrate, ion-implanting impurities into the semiconductor layer so as to form a channel region of a second general conductivity type as an island in the semiconductor layer, ion-implanting impurities of the first general conductivity type into a first portion of the channel region, forming a conductive layer on the first portion of the channel region in which the impurities of the first general conductivity type have been implanted, ion-implanting impurities of the second general conductivity type into a second portion and a third portion of the channel region, diffusing the impurities of the first general conductivity type in the first portion of the channel region to form a gate region of the first general conductivity type, and diffusing the impurities of the second general conductivity type in the second and third portions of the channel region to form a source region of the second general conductivity type and a drain region of the second general conductivity type.

### BRIEF DESCRIPTION OF THE DRAWINGS

FIG. 1A is a plan view and FIG. 1B is a cross-sectional view showing a semiconductor device according to an embodiment of the present invention.

FIG. 2A is a cross-sectional view showing the semiconductor device according to the embodiment of the present invention and FIG. 2B is a cross-sectional view showing another structure for comparison.

FIG. 3 is a plan view showing the semiconductor device according to the embodiment of the present invention.

FIG. 4 is a cross-sectional view showing a method for manufacturing a semiconductor device according to an embodiment of the present invention.

FIGS. 5A and 5B are cross-sectional views showing the method for manufacturing the semiconductor device according to the embodiment of the present invention.

FIGS. 6A and 6B are cross-sectional views showing the method for manufacturing the semiconductor device according to the embodiment of the present invention.

FIGS. 7A and 7B are cross-sectional views showing the method for manufacturing the semiconductor device according to the embodiment of the present invention.

FIG. 8 is a cross-sectional view showing the method for manufacturing the semiconductor device according to the embodiment of the present invention.

FIG. 9A is a plan view and FIG. 9B is a cross-sectional view showing a conventional semiconductor device.

FIGS. 10A to 10D are cross-sectional views showing a method for manufacturing the conventional semiconductor device.

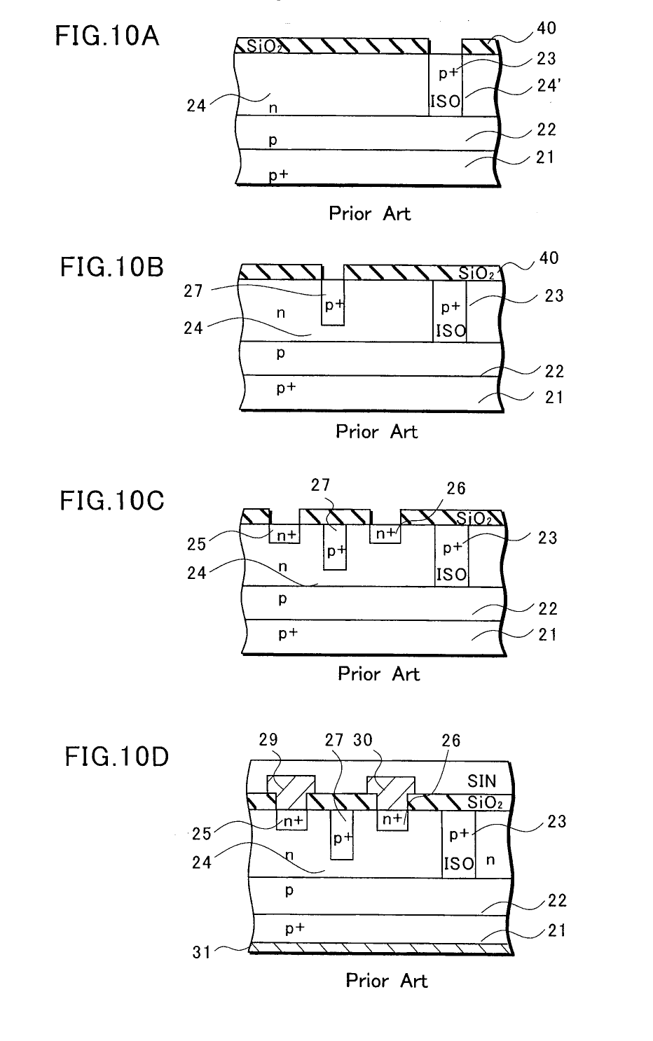

### DESCRIPTION OF THE EMBODIMENTS

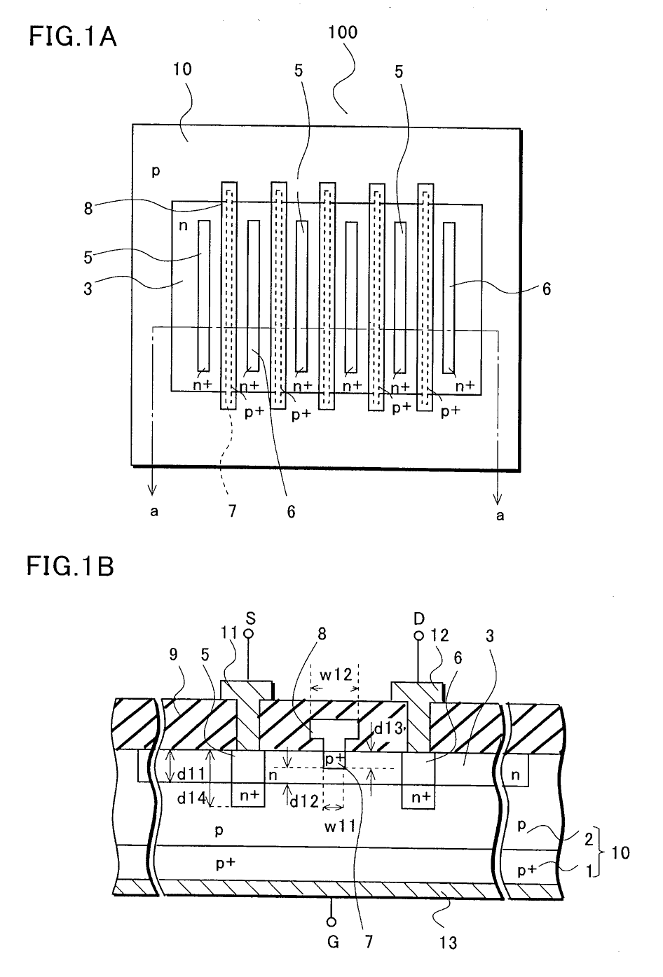

With reference to FIGS. 1 to 8, an embodiment according to the present invention will be described in detail.

FIGS. 1A and 1B show a junction FET 100 of this embodiment. FIG. 1A is a plan view and FIG. 1B is a partial cross-sectional view along the line a-a in FIG. 1A. Note that, in FIG. 1A, an insulating film on a surface of a substrate and metal electrodes (a source electrode and a drain electrode) are omitted. Moreover, FIG. 1B shows one cell represented by a set of a source region, a drain region and a gate region.

The junction FET 100 of the embodiment of the present invention includes a semiconductor substrate 1, a semiconductor layer 2, a channel region 3, source regions 5, drain regions 6, gate regions 7 and conductive layers 8.

With reference to FIG. 1A, an n type channel region 3 is provided in a surface of a p type semiconductor substrate 10. In a surface of the channel region 3, p type gate regions (broken lines) 7 and n type source and drain regions 5 and 6 are provided in a stripe pattern. The conductive layers 8 are provided on the gate regions 7 so as to overlap therewith, and the conductive layers 8 and the gate regions 7 come into contact with each other.

It is noted that conductivity types such as n+, n and n− belong in a general conductivity type, and conductivity types such as p+, p and p− belong in another general conductivity types.

With reference to FIG. 1B, the p type semiconductor substrate 10 is obtained by forming a p type semiconductor layer 2, for example, by epitaxial growth or the like on a p type silicon semiconductor substrate (hereinafter referred to as a p+ type semiconductor substrate) 1. The p type semiconductor layer 2 has an impurity concentration of, for example, about 1.46E16 cm⁻³. The channel region 3 is an island-shaped impurity region formed by selectively ion-implanting and diffusing n type impurities into a surface of the p type semiconductor layer 2. The channel region 3 has an impurity concentration of, for example, about 4.5E16 cm⁻³. A depth d11 of the channel region 3 from the surface of the p type semiconductor layer 2 is about 0.2 μm to 0.5 μm (for example, 0.3 μm). The n type channel region 3 forms a pn junction with the p type semiconductor layer 2 on its side faces and bottom face.

A thickness of the p type semiconductor layer 2 below the channel region 3 is selected according to a breakdown voltage. In this embodiment, the depth d11 of the channel region 3 can be set much smaller than that in the conventional structure. Thus, as to the thickness of the p type semiconductor layer 2 (a depth from the surface of the channel region 3 to the p+ type semiconductor substrate 1), for example, about 8 μm is enough. Specifically, the thickness of the p type semiconductor layer 2 can be set much smaller compared with the conventional structure including the p type epitaxial layer 22 having a thickness of about 10 μm to 13 μm.

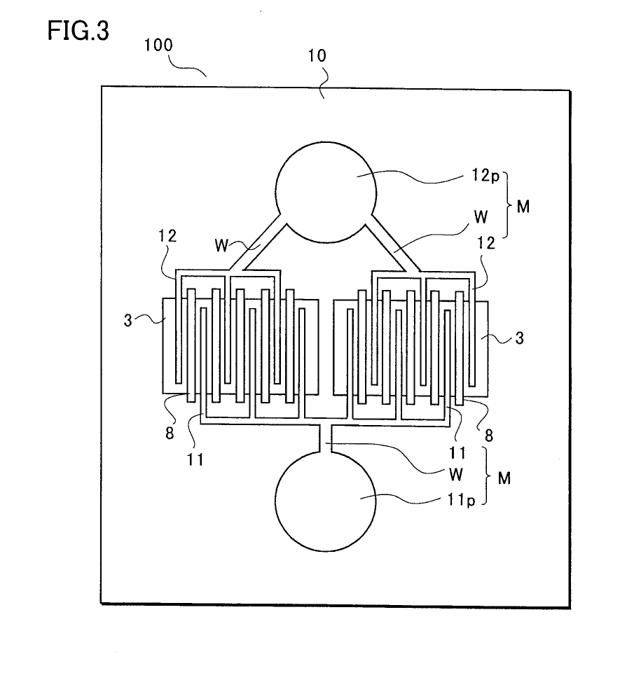

The source region 5 and the drain region 6 are high-concentration (about 3E19 cm⁻³) impurity regions formed by implanting and diffusing n type impurities into the surface of the channel region 3. An insulating film 9 is provided on the surface of the substrate 10, and a source electrode 11 and a drain electrode 12 are provided in a comb-teeth pattern (see FIG. 3). The source and drain electrodes 11 and 12 come into contact with the source and drain regions 5 and 6, respectively, through contact holes provided in the insulating film 9.

A depth d14 of each of the source and drain regions 5 and 6 is about 0.5 μm to 0.7 μm (for example, 0.6 μm) from the surface of the channel region 3. Specifically, each of the source and drain regions 5 and 6 in this embodiment is provided in a part of the inside channel region 3 so as to penetrate the channel region 3 from the surface of the channel region 3 and reach the p type semiconductor layer 2. Therefore, below the bottom face of the channel region 3, the source and drain regions 5 and 6 form pn junctions with the p type semiconductor layer 2, respectively.

The gate region 7 is a p type impurity diffusion region provided between the source and drain regions 5 and 6 in the channel region 3. It is preferable that the gate region 7 has an impurity concentration of about 1E18 cm⁻³. Moreover, a depth d13 of the gate region 7 is about 0.1 μm to 0.2 μm from the surface of the channel region 3.

One cell includes a set of the source, drain and gate regions 5 to 7 shown in FIG. 1B, and a plurality of cells are arranged in one channel region 3 as shown in FIG. 1A.

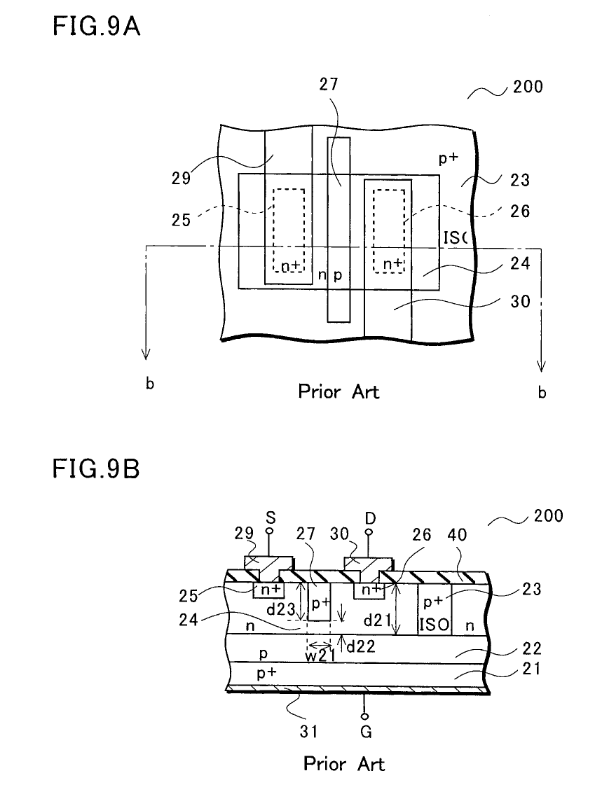

In this embodiment, the same I_{DSS} as that of the junction FET 200 having the conventional structure shown in FIGS. 9A and 9B is maintained, and a gate length w11 and a depth d12 immediately below the gate region 7 are set the same as those in the conventional structure, respectively (w11=w21 and d12=d22). Moreover, the impurity concentration of the channel region 3 is also set the same as that in the conventional structure.

The gate region 7 comes into contact with the conductive layer 8 provided thereon. The conductive layer 8 is a polysilicon layer containing p type impurities and can reduce a gate resistance. The gate resistance becomes an input resistance and significantly affects noise or strain characteristics. However, according to this embodiment, noise characteristics can be improved. Specifically, in order to reduce the gate resistance, it is desirable to secure a large cross-sectional area of the conductive layer 8. However, it is necessary to reduce a capacitance in the gate region 7. Thus, the conductive layer 8 is provided in such a manner that a width w12 thereof above a contact portion with the gate region 7 is set larger than a width (the gate length) w11 of the contact portion.

The conductive layer 8 is extended to the surface of the p type semiconductor layer 2 outside the channel region 3 (see FIG. 1A). Moreover, a gate electrode 13 is provided on a back surface of the p+ type semiconductor substrate 1. The gate region 7 is electrically connected to the gate electrode 13 through the conductive layer 8, the p type semiconductor layer 2 and the p+ type semiconductor substrate 1.

Note that, in FIG. 1B, the conductive layer 8 does not have to be provided. In such a case, the gate resistance is increased. However, since the conductive layer 8 is formed in a separate step from the gate region 7, the number of steps can be reduced without providing the conductive layer 8 as long as desired characteristics can be maintained.

In this embodiment, the channel region 3 is formed in an island shape in the surface of the p type semiconductor layer 2 by ion implantation and diffusion. Specifically, it is possible to form the channel region 3 having the small depth d11 from the surface of the p type semiconductor layer 2. The depth d11 of the channel region 3 in this embodiment is, for example, 0.3 μm. Thus, compared with the conventional structure (FIGS. 9A and 9B) in which the depth d21 of the channel region 24 is about 2 μm, a pn junction area can be reduced and thus a pn junction capacitance can be reduced.

Here, a cutoff frequency f_{T} representing high-frequency characteristics of the junction FET is expressed by the following equation:

f_{T}=gm/(2πC_{G})

wherein gm is a mutual conductance and C_{G} is a sum of a gate-source junction capacitance and a gate-drain junction capacitance.

In other words, a gate junction capacitance that is the sum of the gate-source junction capacitance and the gate-drain junction capacitance significantly affects the high-frequency characteristics of the junction FET 100.

The source and drain regions 5 and 6 of the same conductivity type are provided in the channel region 3, and the channel region 3 is connected thereto. Moreover, the p type semiconductor layer 2 and the p+ type semiconductor substrate 1 are electrically connected to the gate region 7 through the conductive layer 8. Specifically, reduction in the pn junction capacitance between the gate region 7 (the semiconductor layer 2) and the channel region 3 (and the source and drain regions 5 and 6 below the channel region 3) leads to reduction in the gate-source junction capacitance C_{GS} and the gate-drain junction capacitance C_{GD}. Consequently, the high-frequency characteristics can be improved by reducing the combined capacitance (gate capacitance C_{G}).

In the conventional structure, the pn junction area formed by the channel region 24, the p type epitaxial layer 22 and the p+ type isolation region 23 is constrained by the thickness of the n type epitaxial layer 24′ (the depth of the channel region 24) d21. Thus, there is a problem that improvement of high-frequency characteristics cannot be achieved by reduction in the pn junction capacitance.

However, in this embodiment, by forming the channel region 3 by ion implantation, the depth d11 thereof can be set sufficiently small. Thus, the pn junction area can be reduced. Note that the pn junction area is slightly increased by the source and drain regions 5 and 6 penetrating the channel region 3. However, the depth d11 of the channel region 3 is significantly reduced compared with the depth d21 in the conventional structure. Moreover, reduction in the pn junction area by the reduction in the depth of the channel region far exceeds the increase in the pn junction area by the source and drain regions 5 and 6. Thus, it is possible to contribute to reduction in the gate capacitance C_{G}.

Therefore, the cutoff frequency f_{T} can be improved by the reduction in the pn junction capacitance. To be more specific, the cutoff frequency f_{T} of 560 MHz in the conventional structure can be improved to 750 MHz according to this embodiment.

Furthermore, according to this embodiment, noise (NF) characteristics can also be improved, which will be described below.

First, end portions (the side faces and bottom face) of the channel region 3 form pn junctions with the p type semiconductor layer 2. Specifically, compared with the conventional structure in which the channel region forms the pn junction with the isolation region 23 that is a high concentration (about 1E19 cm⁻³) impurity region, a difference in impurity concentration between the pn junctions on the side faces of the channel region 3 can be reduced. The reduction in the difference in impurity concentration makes it possible to extend an initial depletion layer between the pn junctions and also to reduce the pn junction capacitance. Thus, leak currents I_{GSS} on the side faces of the channel region 3 can be reduced.

Next, as described above, the I_{DSS} (or a pinch-off voltage) of the junction FET 100 is determined by the depth d12 immediately below the gate region 7, the impurity concentration of the channel region 3 and the width (the gate length w11) of the gate region 7.

In this embodiment, the same I_{DSS} (or pinch-off voltage) as that of the junction FET 200 having the conventional structure shown in FIGS. 9A and 9B for comparison is maintained. In addition, the gate length w11 and the depth d12 immediately below the gate region 7 are set the same as those in the conventional structure, respectively (w11=w21 and d12=d22). Moreover, the impurity concentration of the channel region 3 is also set the same as that in the conventional structure.

In this embodiment, the depth d12 immediately below the gate region 7 is, for example, 0.1 μm to 0.2 μm. Specifically, in order to achieve the same I_{DSS} (or pinch-off voltage) (to set the depth d22 immediately below the gate region to 0.1 μm to 0.2 μm) in the conventional structure including the channel region 24 having the depth d21 of about 2 μm, it is necessary to form the gate region 27 to have a sufficiently large depth d23. In other words, the signal path from the source region 25 through below the gate region 27 to the drain region 26 in the junction FET 200 is extended.

Meanwhile, in this embodiment, since the channel region 3 is shallow, the gate region 7 can also be formed to be shallow. If a desired value can be secured as the depth d12 immediately below the gate region 7, it is advantageous for reduction in the gate capacitance C_{G} to set the depth d13 of the gate region 7 as small as possible.

Moreover, by reducing the depth d13 of the gate region 7, a signal path from the source region 5 through below the gate region 7 to the drain region 6 in the junction FET 100 can be shortened compared with that in the conventional structure. Therefore, an internal resistance can be reduced by the shortened signal path.

Furthermore, the source and drain regions 5 and 6 as the high-concentration impurity regions penetrate the channel region 3. Therefore, it is possible to increase an area of the high-concentration impurity regions having a low resistance in the signal path. Thus, this is advantageous for reduction in the internal resistance.

Furthermore, lateral diffusion (diffusion in horizontal directions of the substrate 10) of the diffusion region is also extended according to the depth thereof. Thus, the lateral diffusion can also be suppressed if the gate region 7 can be formed to be shallow. Therefore, a distance between the source and drain regions 5 and 6 can be reduced. In this case, reduction in the distance therebetween contributes to improvement in cell density and reduction in the signal path. This also enables reduction in the internal resistance of the channel region 3.

Furthermore, the gate region 7 comes into contact with the conductive layer 8 provided thereon. The gate resistance can be reduced by the conductive layer 8. Since the gate resistance affects noise, input signal distortion and the like, these can be improved by reduction in the gate resistance.

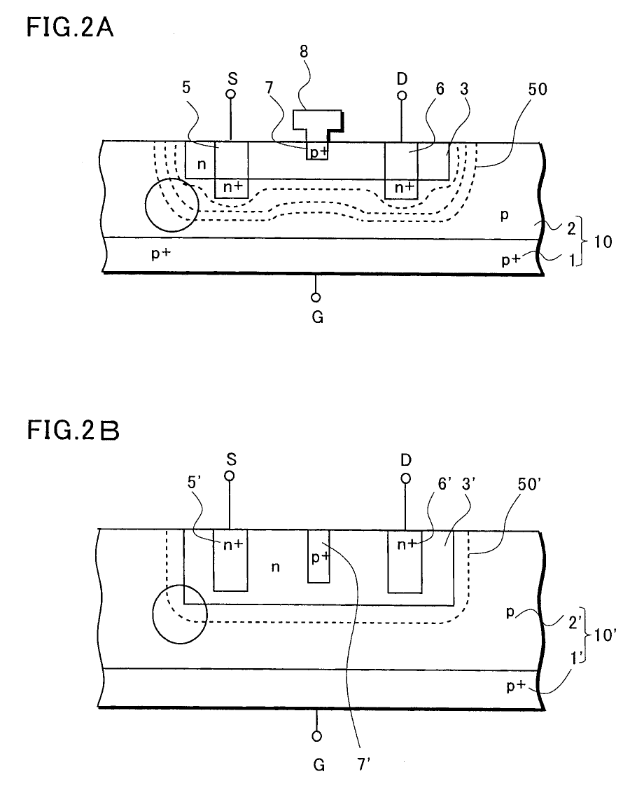

Next, with reference to FIGS. 2A and 2B, the source region 5 and the drain region 6 will be described.

FIG. 2A is a view showing spread of a depletion layer in this embodiment. FIG. 2B is a view showing the case where a deep channel region 4′ is formed by ion implantation for comparison.

As shown in FIG. 2A, the source and drain regions 5 and 6 in this embodiment penetrate the channel region 3 and reach the p type semiconductor layer 2. Specifically, the side faces and bottom face of the channel region 3 and side faces and bottom faces of the source and drain regions 5 and 6 protruding below the channel region 3 form pn junctions with the p type semiconductor layer 2, respectively.

In the structure shown in FIG. 2A, when a reverse bias is applied, a depletion layer 50 is spread as indicated by broken lines in FIG. 2A. The depletion layer 50 is initially spread along the channel region 3, the source region 5 and the drain region 6. However, along with an increase in the reverse bias, unevenness of the depletion layer 50 spread around the source and drain regions 5 and 6 is reduced. Accordingly, in a bottom corner (indicated by a circle) of the channel region 3, the depletion layer 50 is smoothly spread.

Meanwhile, in FIG. 2B, depths of source and drain regions 5′ and 6′ are set the same as those in FIG. 2A, and a channel region 3′ deeper than the source and drain regions is provided. In this case, when a reverse bias is applied, side faces and bottom face of the channel region 3′ form pn junctions with a p type semiconductor layer 2′. Therefore, a depletion layer 50′ is spread along the channel region 3′ as indicated by a broken line.

As described above, in this embodiment, a so-called graft base structure is achieved by the shallow channel region 3 and the source and drain regions 5 and 6 penetrating therethrough. Thus, a curvature of the depletion layer 50 can be reduced (the circle in FIG. 2A) compared with that in a bottom corner of the channel region 3′ indicated by a circle in FIG. 2B. Thus, a breakdown voltage can be improved.

In order to obtain good noise characteristics at a high cutoff frequency f_{T} in the conventional structure (FIGS. 9A and 9B) or in the structure shown in FIG. 2B, it is necessary to increase the impurity concentration of the channel region. Thus, there is a limit on improvement in the breakdown voltage. However, according to this embodiment, the structure like a graft base of a bipolar transistor is achieved by the source and drain regions 5 and 6. Thus, a high breakdown voltage can be obtained as the impurity concentration of the channel region 3 is maintained to be low (about 4.5E16 cm⁻³).

For example, in a J-FET 200 having the conventional structure in which a cutoff frequency is 550 MHz and a breakdown voltage is 25V, when the cutoff frequency f_{T} of 750 MHz is realized by increasing the impurity concentration of the channel region 24, the breakdown voltage is deteriorated to 10 V.

Meanwhile, in this embodiment, the breakdown voltage can be set to 46 V with the impurity concentration of the channel region 3 that achieves the cutoff frequency f_{T} of 750 MHz.

Furthermore, according to this embodiment, electrostatic breakdown characteristics are improved.

In the conventional structure, in order to improve the electrostatic breakdown characteristics, it is required to increase the impurity concentration of the channel region. However, there is a problem that the impurity concentration thereof cannot be increased more than necessary in consideration of the breakdown voltage. Meanwhile, in this embodiment, the source and drain regions 5 and 6 as the high-concentration impurity regions and the p type semiconductor layer 2 form junctions. As to electrostatic breakdown of the pn junctions in the J-FET, the pn junction with a higher impurity concentration has more charges that can be electrified and thus is more advantageous than the pn junction with a lower impurity concentration.

Specifically, in this embodiment, the electrostatic breakdown characteristics can be improved without increasing the impurity concentration of the channel region 3.

FIG. 3 is a view showing an example of wirings in this embodiment.

Here, FIG. 3 shows the case where two channel regions 3 shown in FIGS. 1A and 1B are disposed and connected in parallel by a metal electrode layer M. However, the channel regions 3 may be one continuous region.

On each of the channel regions 3, a source electrode 11 and a drain electrode 12 are provided, which are connected to source regions and drain regions while overlapping therewith, respectively. The source and drain electrodes 11 and 12 are arranged in a comb-teeth pattern. The source electrode 11 is connected to a source pad electrode 11p through one wiring W, and the drain electrode 12 is connected to a drain pad electrode 12p through two wirings W extended from the respective channel regions 3.

The gate regions are connected to a gate electrode (not shown) provided on the back surface of the p type semiconductor substrate 10 through the conductive layers 8 and the p type semiconductor substrate 10.

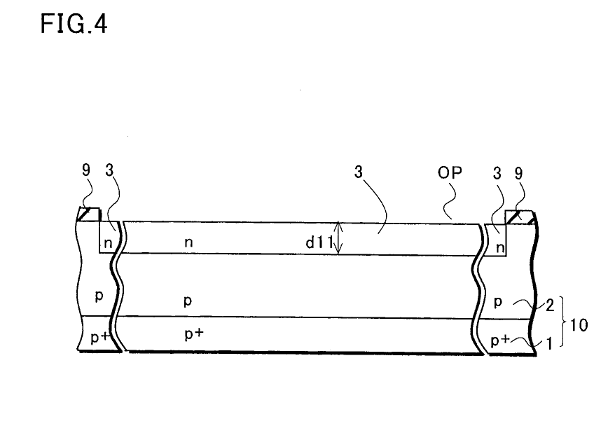

Next, with reference to FIGS. 4 to 8, description will be given of a method for manufacturing a junction FET according to an embodiment of the present invention.

First step (FIG. 4): providing a one conductivity type semiconductor layer on a one conductivity type semiconductor substrate, and forming an opposite conductivity type channel region by ion-implanting opposite conductivity type impurities into a surface of the one conductivity type semiconductor layer, the channel region having end portions forming pn junctions with the one conductivity type semiconductor layer.

A semiconductor substrate 10 is prepared, which has a p type semiconductor layer 2 laminated by epitaxial growth or the like on a p+ type semiconductor substrate 1. An insulating film (for example, an oxide film) 9 is formed on a surface of the p type semiconductor layer 2, and an opening is provided at a predetermined position of the insulating film. Thereafter, n type impurities are selectively ion-implanted and diffused in the opening. The impurities are, for example, phosphorus (P+), and ion implantation conditions include a dose of 5E12 cm⁻² to 2E13 cm⁻² and implantation energy of 140 KeV. Moreover, diffusion conditions include a temperature of 1100° C. and a duration of 150 to 300 minutes, for example. Accordingly, an island-shaped channel region 3 is formed, which has a depth d11 of about 0.2 μm to 0.5 μm (for example, 0.3 μm) from the surface of the p type semiconductor layer 2 and an impurity concentration of about 4E16 cm⁻³. The channel region 3 forms pn junctions with the p type semiconductor layer 2 on its end portions (side faces and bottom face).

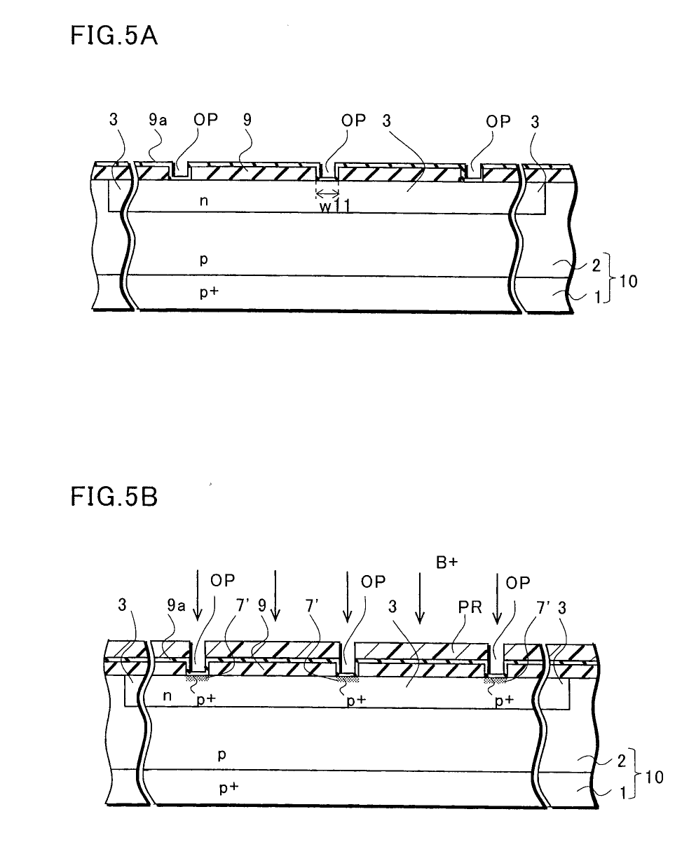

Second step (FIGS. 5A and 5B): ion-implanting one conductivity type impurities into a surface of the channel region.

The insulating film (oxide film) 9 is formed again on the entire surface so as to have a thickness of about 4000 Å, and openings OP are formed in formation regions of gate regions. A width w11 of each of the openings OP becomes a gate length. Thereafter, an additional insulating film (oxide film) 9a is formed on the entire surface so as to have a thickness of about 500 Å. The insulating film 9a serves as a mask for reducing an average projected range of ion implantation in the gate regions (FIG. 5A).

Next, a mask is provided by use of a photoresist PR so as to expose only the openings OP.

On the entire surface, ion implantation of p type impurities is performed. The impurities are, for example, boron (B+), and implantation energy is 80 KeV and a dose is about 1E14 cm⁻². The impurities are ion-implanted into sufficiently shallow regions through the insulating film 9a which is provided in the openings OP and has the thickness of 500 Å. Thus, p type gate impurity implantation regions 7′ are formed (FIG. 5B).

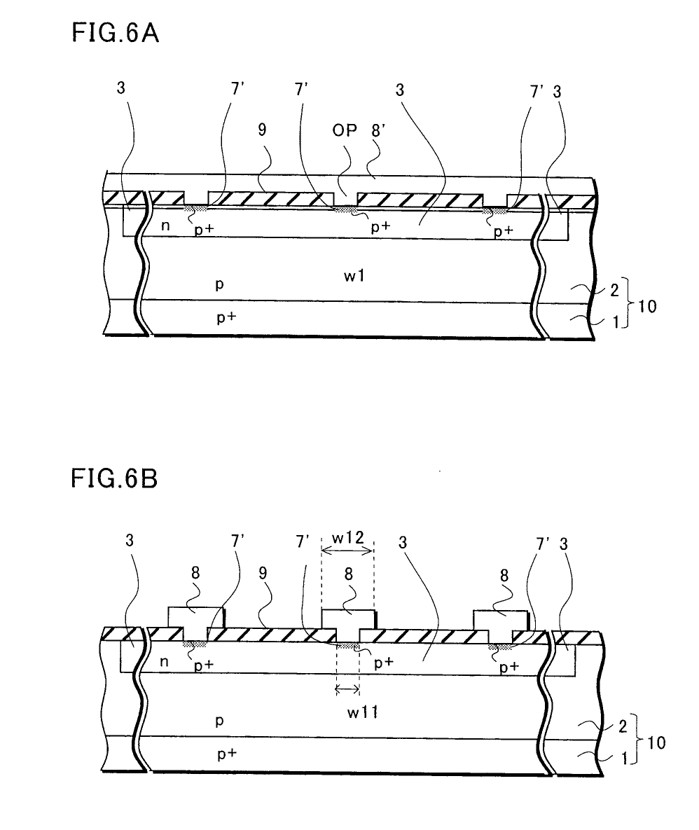

Third step (FIGS. 6A and 6B): forming conductive layers on the surface of the channel region.

The photoresist PR and the insulating film 9a are removed. Thereafter, a polysilicon layer 8′ (thickness of 2000 Å) is deposited on the entire surface of the insulating film 9 exposed. Subsequently, impurities (boron (B+) at a dose of 7E15 cm⁻²) are introduced (implantation energy: 30 KeV) into the polysilicon layer 8′ in order to reduce a resistance. The polysilicon layer 8′ comes into contact with the gate impurity implantation regions 7′ through the openings OP (FIG. 6A).

Thereafter, a mask having a desired pattern is provided, and the polysilicon layer 8′ is patterned to form conductive layers 8. Each of the conductive layers 8 is patterned in such a manner that a width w12 of its upper surface is set larger (for example, about 4 μm) than a width w11 of its bottom face (for example, 1 μm).

The conductive layers 8 serve for connecting gate regions and gate electrodes with each other, which are to be formed in subsequent steps, and contribute to reduction in a gate resistance. It is desirable for reduction in a gate capacitance that the gate length (width of the bottom face of the conductive layer 8) w11 is small. Therefore, the conductive layer 8 has a shape in which the width w12 of the upper surface is larger than the width w11 of the bottom face (FIG. 6B).

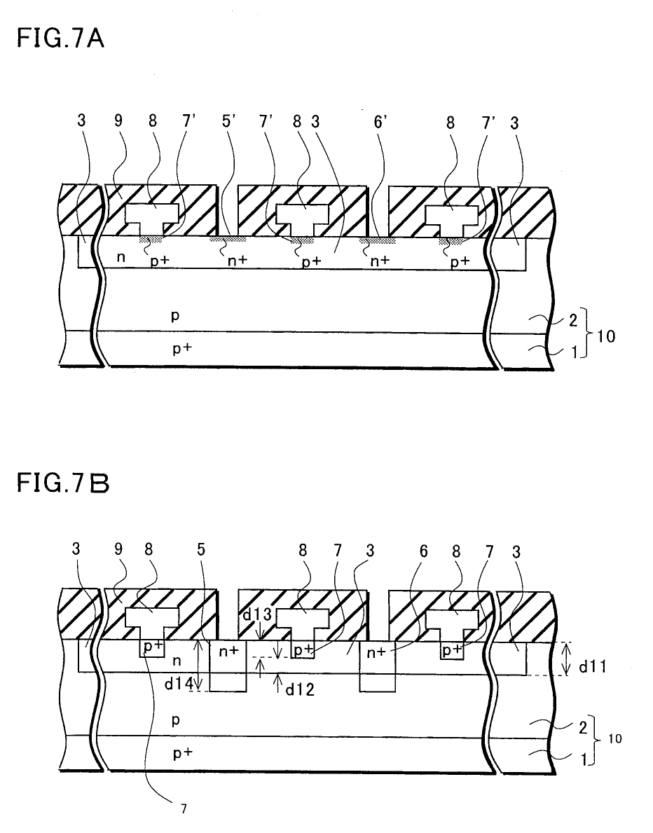

Fourth step (FIGS. 7A and 7B): forming one conductivity type gate regions in the surface of the channel region, and forming opposite conductivity type source and drain regions, which penetrate the channel region, in a part of the channel region.

The insulating film 9 is formed again on the entire surface, and openings are formed in the insulating film 9 so as to correspond to formation regions of source and drain regions. Thereafter, n type impurities (dose: 5E15 cm⁻² and implantation energy: 100 KeV) are ion-implanted into the entire surface to form a source impurity implantation region 5′ and a drain impurity implantation region 6′ (FIG. 7A).

Thereafter, heat treatment (for example, about 950° C. for 20 minutes) is performed. Thus, the n type impurities in the source impurity implantation region 5′ and the drain impurity implantation region 6′ are diffused into the channel region 3 to form a source region 5 and a drain region 6. Moreover, at the same time, the impurities in the gate impurity implantation regions 7′ are diffused to form gate regions 7, which come into contact with the conductive layers 8, below the conductive layers. A depth d13 of the gate region 7 from the surface of the channel region 3 is 0.1 μm to 0.2 μm, and a depth d12 immediately below the gate region 7, which determines I_{DSS} (or a pinch-off voltage), is set to 0.1 μm to 0.2 μm.

As described above, since the gate region 7 may be formed by shallow diffusion, heat treatment time can be reduced compared with the conventional case. For example, in the conventional structure shown in FIGS. 9A and 9B, heat treatment time required to form the gate region 27 is 1 hour. Meanwhile, in this embodiment, the heat treatment time can be reduced to ⅓ (about 20 minutes). Moreover, since the heat treatment time is short, lateral diffusion can also be suppressed.

The source and drain regions 5 and 6 are formed to have an impurity concentration of about 3E19 cm⁻³. The source and drain regions 5 and 6 have a depth d14 of about 0.5 μm from the surface of the channel region 3, and penetrate the channel region 3 and reach the p type semiconductor layer 2 (FIG. 7B).

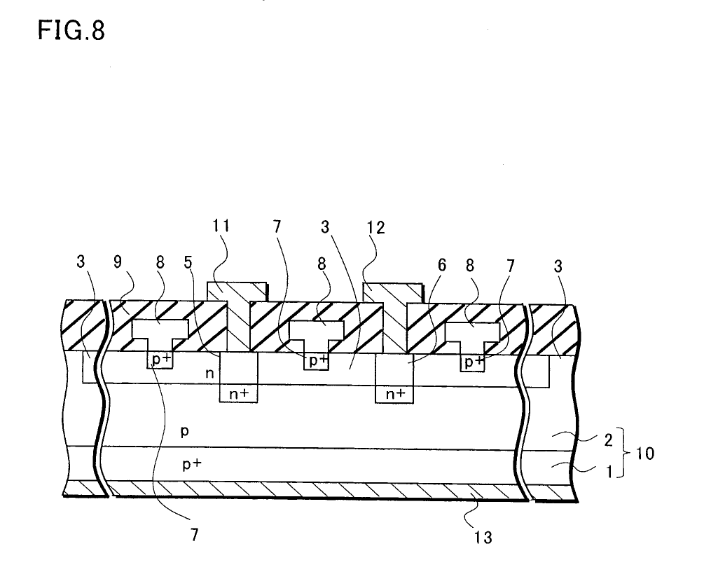

Fifth step (FIG. 8): forming electrodes connected to the respective regions.

While leaving the insulating film 9 as it is on the surface of the substrate, metal such as Al is deposited and patterned into a predetermined electrode structure. Thus, a source electrode 11 and a drain electrode 12 are formed, which come into contact with the source region 5 and the drain region 6, respectively. Moreover, a gate electrode 13 is formed on a back surface of the substrate. The gate electrode 13 is connected to the gate regions 7 through the p+ type semiconductor substrate 1, the p type semiconductor layer 2 and the conductive layers 8.

According to the present invention, the following effects can be achieved.

First, by forming the channel region by ion implantation, the depth of the channel region can be set small. Thus, a pn junction area between the gate region (the p type semiconductor layer) and the channel region can be reduced compared with the conventional structure. As a result, high-frequency characteristics can be improved by improvement in the cutoff frequency f_{T}.

Secondly, the channel region forms pn junctions with the p type semiconductor layer having an impurity concentration lower than that in the conventional structure. Thus, compared with the conventional structure (FIGS. 9A and 9B) in which the isolation region that is a high-concentration p type impurity region and the channel region (well region) form the pn junctions, a difference in impurity concentration between the pn junctions on the end portions (side faces) of the channel region can be reduced. The reduction in the difference in impurity concentration between the pn junctions makes it possible to reduce leak currents I_{GSS} on the end portions of the channel region.

Third, along with the channel region, the gate region can also be formed to be shallower than that in the conventional structure. Specifically, when the depth immediately below the gate region is set the same as that in the conventional structure in order to maintain the same I_{DSS} as that of the conventional structure, the gate region can also be shallowly formed to the extent that the channel region is shallowly formed.

Thus, a signal path from the source region through below the gate region to the drain region can be shortened, and noise characteristics can be improved by reduction in an internal resistance.

Moreover, the smaller the depth of diffusion of the gate region, the more the lateral diffusion of the gate region is reduced. Since the source and drain regions are provided at a predetermined distance from the gate region, distances (patterns) between the source region and the gate region and between the drain region and the gate region can be reduced. Therefore, the signal path can be further reduced to contribute to improvement in the noise characteristics.

Fourth, by providing the conductive layer which comes into contact with the gate region, the gate resistance can be reduced. The gate resistance becomes an input resistance and significantly affects noise and strain characteristics. However, according to this embodiment, the noise and strain characteristics can be improved.

Fifth, since it is not necessary to stack an epitaxial layer to be a channel region, wafer cost is reduced.

Sixth, the source and drain regions which are high-concentration impurity regions are provided so as to penetrate the channel region. Thus, in the signal path formed inside the channel region, an area of the high-concentration impurity regions is increased. Consequently, a resistance of the signal path is reduced, which is advantageous for noise characteristics.

Seventh, the source and drain regions which penetrate the channel region are formed to have a structure such as a graft base structure of a bipolar transistor. Thus, it is possible to reduce a curvature in an end portion of a depletion layer spread in the pn junction between the channel region and the semiconductor layer. As a result, a breakdown voltage can be increased even if the impurity concentration of the channel region is maintained to be the same as that in the conventional structure.

Eighth, the electrostatic breakdown characteristics are improved. In order to improve the electrostatic breakdown characteristics, it is necessary to increase the impurity concentration of the channel region. On the other hand, an increase in the impurity concentration of the channel region leads to a problem of deterioration of the breakdown voltage. Therefore, when a predetermined breakdown voltage (for example, 30V) is maintained in the conventional structure, improving the electrostatic breakdown characteristics by increasing the impurity concentration cannot be adopted.

However, in this embodiment, the source and drain regions, which are the high-concentration impurity regions, and the p type semiconductor layer form junctions. Thus, good electrostatic breakdown characteristics can be achieved without increasing the impurity concentration of the channel region (while maintaining the same impurity concentration as that in the conventional structure).

According to the manufacturing method of the present invention, first, an isolation region formation step can be eliminated. Specifically, since the channel region is formed by ion implantation into the p type semiconductor layer, the step of forming the p+ type isolation region, which has heretofore been required for isolation of the n type epitaxial layer is no longer required. The conventional isolation region is formed in a separate step from the gate region and the like, for example. Thus, since the isolation region formation step is no longer required, the manufacturing steps can be simplified.

Secondly, the gate region that is the impurity diffusion region can be shallowly formed. In the conventional structure, it is necessary to form a deep gate region according to the depth of the channel region. Thus, a long period of heat treatment is required. However, according to this embodiment, the heat treatment time required to form the gate region can be reduced to ⅓ of that in the conventional case, for example.

What is claimed is:

1. A junction field effect transistor comprising:
a semiconductor substrate of a first general conductivity type;
a semiconductor layer of the first general conductivity type disposed on the substrate;
a channel region of a second general conductivity type formed in a surface portion of the semiconductor layer so as to form a pn junction with the semiconductor layer on a side and a bottom of the channel region;
a source region of the second general conductivity type formed in the channel region so as to penetrate the channel region to reach the semiconductor layer;
a drain region of the second general conductivity type formed in the channel region so as to penetrate the channel region to reach the semiconductor layer; and
a gate region of the first general conductivity type formed in the channel region.

2. The transistor of claim 1, wherein the source and drain regions are configured to form pn junctions with the semiconductor layer below the channel region.

3. A junction field effect transistor comprising:
a semiconductor substrate of a first general conductivity type;
a semiconductor layer of the first general conductivity type disposed on the substrate;
a channel region of a second general conductivity type formed in a surface portion of the semiconductor layer so as to define an island of the channel region in the semiconductor layer;
a source region of the second general conductivity type formed in the channel region so as to penetrate the channel region to reach the semiconductor layer;
a drain region of the second general conductivity type formed in the channel region so as to penetrate the channel region to reach the semiconductor layer;
a gate region of the first general conductivity type formed in the channel region; and
a conductive layer disposed on and in contact with the gate region.

4. The transistor of claim 3, wherein the conductive layer comprises a semiconductor layer containing impurities.

5. The transistor of claim 3, wherein a width of an upper surface of the conductive layer is larger than a width of the gate region.

6. The transistor of claim 3, wherein the source and drain regions are configured to form pn junctions with the semiconductor layer below the channel region.

7. A method of manufacturing a junction field effect transistor, comprising:
providing a semiconductor substrate of a first general conductivity type;
forming a semiconductor layer of the first general conductivity type on the substrate;
ion-implanting impurities into the semiconductor layer so as to form a channel region of a second general conductivity type;
forming a source region of the second general conductivity type in the channel region so as to penetrate the channel region to reach the semiconductor layer;
forming a drain region of the second general conductivity type in the channel region so as to penetrate the channel region to reach the semiconductor layer; and
forming a gate region of the first general conductivity type in the channel region.

8. A method of manufacturing a junction field effect transistor, comprising:
providing a semiconductor substrate of a first general conductivity type;
forming a semiconductor layer of the first general conductivity type on the substrate;
ion-implanting impurities into the semiconductor layer so as to form a channel region of a second general conductivity type as an island in the semiconductor layer;
ion-implanting impurities of the first general conductivity type into a first portion of the channel region;
forming a conductive layer on the first portion of the channel region in which the impurities of the first general conductivity type have been implanted;
ion-implanting impurities of the second general conductivity type into a second portion and a third portion of the channel region;
diffusing the impurities of the first general conductivity type in the first portion of the channel region to form a gate region of the first general conductivity type; and
diffusing the impurities of the second general conductivity type in the second and third portions of the channel region to form a source region of the second general conductivity type and a drain region of the second general conductivity type.

9. The method of claim 8, wherein the diffusion of the impurities of the first general conductivity type and the diffusion of the impurities of the second general conductivity type are performed in the same process step.
